(19) United States
(12) Patent Application Publication
(10) Pub. No.: US 2016/0034739 A1
(43) Pub. Date: Feb. 4, 2016

(54) BIOMETRIC IDENTIFICATION DEVICE HAVING SENSOR ELECTRODES WITH MASKING FUNCTION

(71) Applicant: SuperC-Touch Corporation, New Taipei City (TW)

(72) Inventor: Shang CHIN, New Taipei City (TW)

(21) Appl. No.: 14/813,536

(22) Filed: Jul. 30, 2015

(30) Foreign Application Priority Data
Aug. 1, 2014 (TW) 103213650

(51) Int. Cl. G06K 9/00; H01L 27/12

(52) U.S. Cl. CPC G06K 9/0002; H01L 27/124; H01L 27/1218; H01L 27/1255

(57) ABSTRACT

A biometric identification device includes a substrate, plural sensor electrodes; plural selectors, plural selection traces, plural sensing signal readout lines, and a control unit. The sensor electrodes disposed on the substrate. Each selector corresponds to one sensor electrode and has a first terminal, a second terminal and a third terminal. The first terminal is connected to a corresponding sensor electrode. Each selection trace is connected to the second terminal of at least one selector. Each sensing signal readout line is connected to the third terminal of at least one selector. The control unit is connected to the selectors through the selection traces and the sensing signal readout lines, so as to read sensed signals of the sensor electrodes. The selectors, the selection traces, and the sensing signal readout lines are disposed below and masked by the sensor electrodes.

### BACKGROUND OF THE INVENTION

1. Field of the Invention

The present invention relates to a structure of a biometric identification device and, more particularly, to a biometric identification device having sensor electrodes with masking function.

2. Description of Related Art

Biological feature sensing and comparing technologies have been maturely and widely applied in identifying and verifying the identity of a person. Typical biometric identification types include fingerprint, voiceprint, iris, retina identification, and the like. For consideration of safe, comfortable, and efficient identification, the fingerprint identification has become the most popular one. The fingerprint identification generally requires a scanning to input a fingerprint or a finger image of a user and store the unique features of the finger image and/or the fingerprint for being further compared with the fingerprint reference data built in a database so as to identify or verify the identity of a person.

The image input types of the fingerprint identification include optical scanning, thermal image sensing, capacitive sensing, and the like. The optical scanning type is difficult to be applied in a mobile electronic device due to its large volume, and the thermal image sensing type is not popular due to its poor accuracy and reliability. Thus, the capacitive sensing type gradually becomes the most important biometric identification technology for the mobile electronic device.

In prior capacitive image sensing technology, the sensor electrodes and the detecting circuit are typically implemented on a single integrated circuit (IC) to increase the signal to noise ratio (SNR) and signal detection quality. The capacitive image sensing can be divided into two types, including a linear swiping scan and a full area detection. The positioning recovery of the former one is difficult, which may cause the image distortion and poor image quality. The latter one requires an IC manufacturing process to make sensing electrodes, which results in a large wafer area to be used and a relatively high cost. In addition, both of them have the drawbacks of complicated and difficult in packaging, poor mechanical strength, fragility, susceptible to moisture erosion damage, and the like, and thus the reliability and the usage lifetime of the device are not users satisfied.

FIG. 1 is a schematic diagram of a typical capacitive sensing. As shown in FIG. 1, there is a substrate 110 implemented thereon a plurality of sensor electrodes 120. Each sensor electrode 120 is electrically connected to a controller 140 via a corresponding trace 130. The controller 140 respectively drives the plurality of sensing electrodes 120 to perform a self-capacitance sensing to thereby obtain a fingerprint image. The typical sensor electrode 120 has a size of about 5 mm×5 mm or below. The trace 130 has a width much smaller than that of the sensor electrode 120. When the size of the sensor electrode 120 is reduced to increase the image sensing resolution, the amount of electricity induced on the trace 130 may cause a significant influence to that of the sensor electrode 120, resulting in that the size of the sensor electrode 120 in the prior art cannot be effectively reduced.

Therefore, it is desirable to provide an improved fingerprint identification device for increasing the mechanical strength and the usage lifetime, reducing the manufacturing cost and increasing the resolution, so as to mitigate and/or obviate the aforementioned problems.

### SUMMARY OF THE INVENTION

The object of the present invention is to provide a biometric identification device having sensor electrodes with masking function, which uses the producing TFT process of the liquid crystal panel firms to greatly save the material cost and raise the SNR. In addition, it is suitable for a high-resolution biometric identification device.

To achieve the object, there is provided a biometric identification device having sensor electrodes with masking function, which comprises: a substrate having a surface; a plurality of sensor electrodes disposed on the surface of the substrate to form a sensing plane; a plurality of selectors, each corresponding to one sensor electrode and having a first terminal, a second terminal, and a third terminal, wherein the first terminal is connected to a corresponding sensor electrode; a plurality of selection traces, each connected to the second terminal of at least one of the selectors; a plurality of sensing signal readout lines, each connected to the third terminal of at least one of the selectors; and a control unit connected to the plurality of selectors through the plurality of selection traces and the plurality of sensing signal readout lines, so as to read sensed signals of the sensor electrodes corresponding to the selectors, respectively, wherein the plurality of selectors, the plurality of selection traces, and the plurality of sensing signal readout lines are disposed below and masked by the plurality of sensor electrodes.

Other objects, advantages, and novel features of the invention will become more apparent from the following detailed description when taken in conjunction with the accompanying drawings.

### BRIEF DESCRIPTION OF THE DRAWINGS

FIG. 1 is a schematic diagram of a typical capacitive sensing;

FIG. 2 is a schematic diagram of a biometric identification device having sensor electrodes with masking function according to an embodiment of the present invention;

FIG. 3 schematically illustrates a stack view of the biometric identification device according to the present invention;

FIG. 4 is a flowchart for a manufacturing process of the biometric identification device according to the present invention; and

FIG. 5 schematically illustrates an application of the biometric identification device according to the invention.

### DETAILED DESCRIPTION OF THE PREFERRED EMBODIMENT

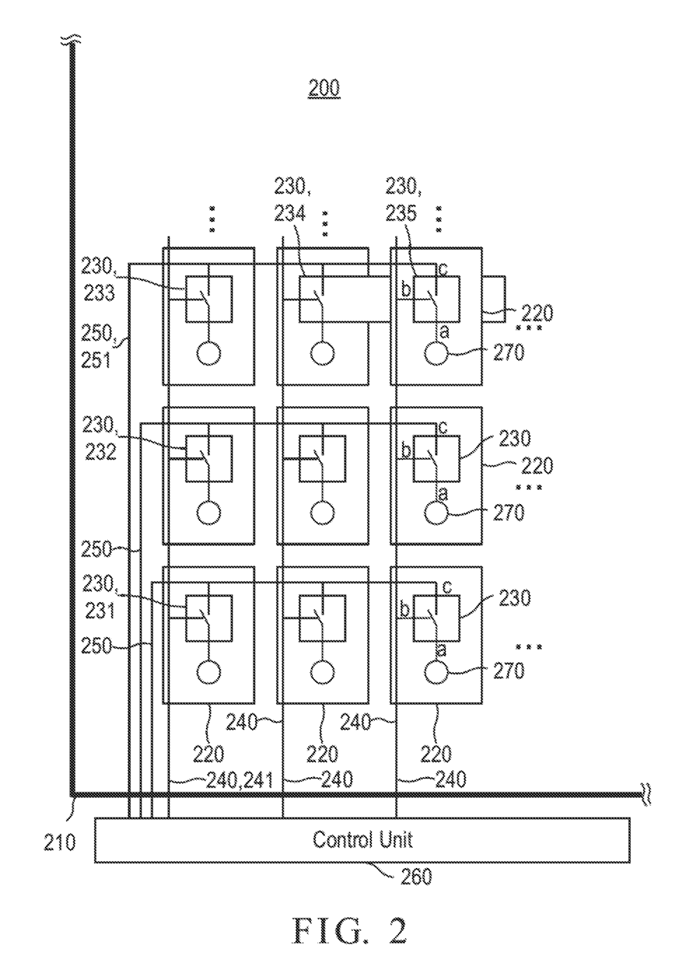

FIG. 2 is a schematic diagram of a biometric identification device 200 having sensor electrodes with masking function according to an embodiment of the present invention. As shown in FIG. 2, the biometric identification device 200 includes a substrate 210, a plurality of sensor electrodes 220, a plurality of selectors 230, a plurality of selection traces 240, a plurality of sensing signal readout lines 250, and a control unit 260.

The substrate 210 can be a polymer thin film or glass. The sensor electrodes 220 are disposed on a surface of the substrate 210 and arranged in rows and columns so as to form a sensing plane. Each of the sensor electrodes 220 can be a polygon, circle, ellipse, rectangle, or square. Each of the sensor electrodes 220 has a width smaller than or equal to 100 μm. Each of the sensor electrodes 220 has a length smaller than or equal to 100 μm.

Each of the sensor electrodes 220 is formed of conductive metal material which is selected from the group consisting of: chromium, barium, aluminum, silver, copper, titanium, nickel, tantalum, cobalt, tungsten, magnesium, calcium, potassium, lithium, indium, and an alloy thereof.

Each of the selectors 230 corresponds to a sensor electrode 220. Each selector 230 has a first terminal (a), a second terminal (b), and a third terminal (c), wherein the first terminal (a) is connected to a corresponding sensor electrode 220 through a via 270.

Each of the selection traces 240 is connected to the second terminal (b) of at least one of the selectors 230. As shown in FIG. 2, the select trace 241 is connected to the second terminals (b) of a column of the selectors 231, 232, 233.

Each of the sensing signal readout lines 250 is connected to the third terminal (c) of at least one of the selectors. As shown in FIG. 2, the sensing signal readout line 251 is connected to the third terminals (c) of a row of the selectors 233, 234, 235.

The control unit 260 is connected to the plurality of selectors 230 through the plurality of select traces 240 and the plurality of sensing signal readout lines 250 for reading the sensed signals of the sensor electrodes 220 corresponding to the selectors 230, respectively. The plurality of selectors 230, the plurality of selection traces 240, and the plurality of sensing signal readout lines 250 are masked by the plurality of sensor electrodes 220. Namely, the selectors 230 are disposed at positions which are the same as those of the sensor electrodes 220 but in different layers. It can be seen from FIG. 2 that the plurality of selectors 230 are completely masked by the plurality of sensor electrodes 220. Similarly, the selection traces 240 and the sensing signal readout lines 250 are arranged at positions which are corresponding to mostly the same positions of the sensor electrodes 220 but in different layers. Specifically, as shown in FIG. 2, each selection trace 240 is a vertical segment that is masked by a column of sensor electrodes 220, and each sensing signal readout line 250 includes a vertical segment and a horizontal segment that is masked by a row of sensor electrodes 220. It thus can be seen from FIG. 2 that most part, for example more than ninety percent, of the selection traces 240 and the sensing signal readout lines 250 is masked by the plurality of sensor electrodes 220.

Each of the selectors 230 is a thin film transistor (TFT). Namely, the biometric identification device 200 of the present invention can be implemented by using the TFT producing process of an LCD firm, which is different from the prior fingerprint identification chip that is implemented on a single IC by using an IC manufacturing process. The IC manufacturing process used in the prior art manufactures related components on a wafer, but the LCD process used in the invention manufactures related components on a glass or polymer thin film. It is known that the glass or polymer thin film is much cheaper than the wafer, and thus the present invention can effectively reduce the manufacturing cost. The thin film transistor has a gate corresponding to the second terminal (b), a source/drain corresponding to the first terminal (a), and the other source/drain corresponding to the third terminal (c).

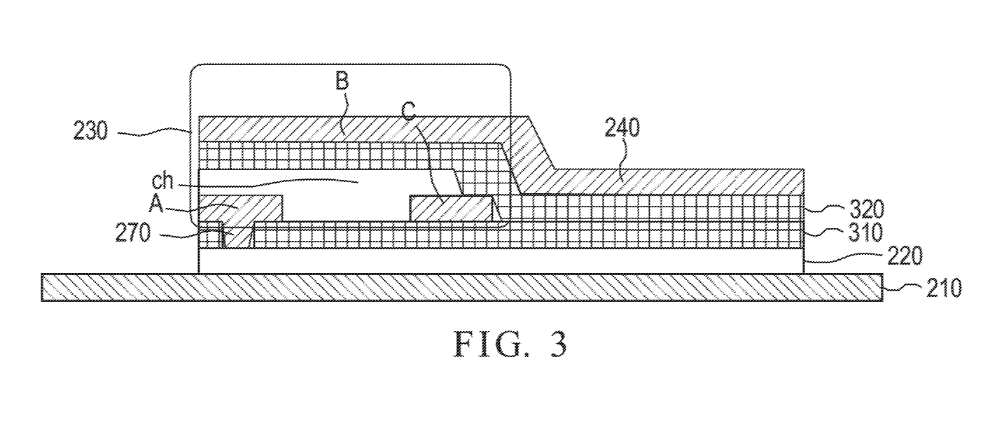

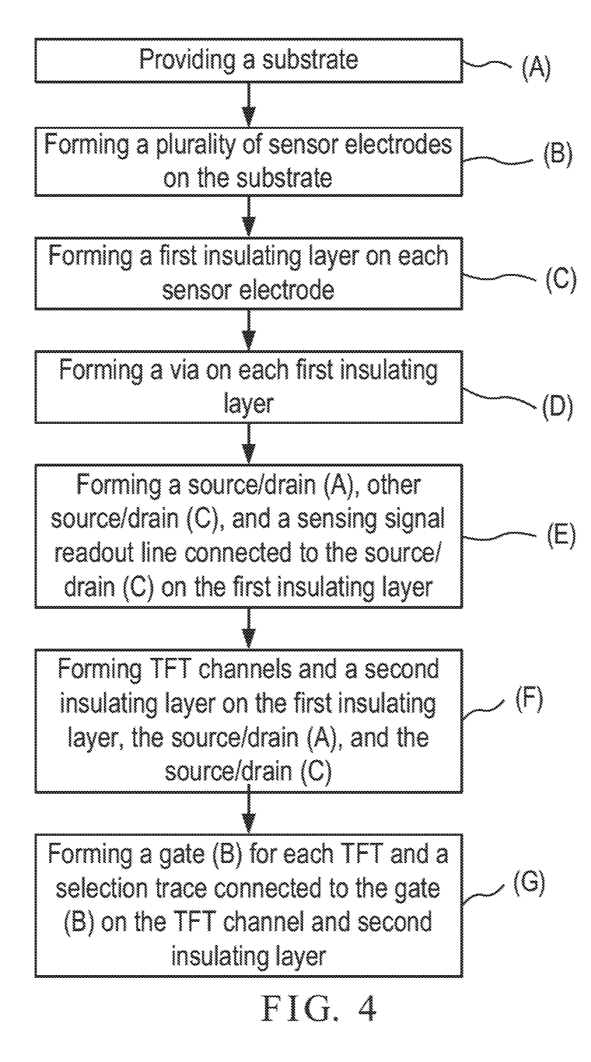

FIG. 3 schematically illustrates a stack view of the biometric identification device according to the present invention. FIG. 4 is a flowchart for a manufacturing process of the biometric identification device 200 of FIG. 2 according to the present invention. As shown in FIGS. 3 and 4, in step (A), a substrate 210 is first provided. The substrate 210 can be a polymer thin film or glass. In step (B), a plurality of sensor electrodes 220 are formed on the substrate 210. In step (C), a first insulating layer 310 is formed on each of the sensor electrodes 220.

In step (D), a via 270 is formed in each first insulating layer 310. In step (E), the source/drain (A) of a TFT channel, the other source/drain (C) of the TFT channel, and a sensing signal readout line 250 connected to the source/drain (C) are formed on each first insulating layer 310. In FIG. 3, the sensing signal readout line 250 connected to the source/drain (C) is perpendicular to the surface of the figure, and thus is not shown.

In step (F), the TFT channel (ch) and a second insulating layer 320 are formed on each first insulating layer 310, the source/drain (A), and the source/drain (C). In step (G), the gate (B) of the thin film transistor and the selection trace 240 connected to the gate (B) are formed on the TFT channel (ch) and the second insulating layer (320).

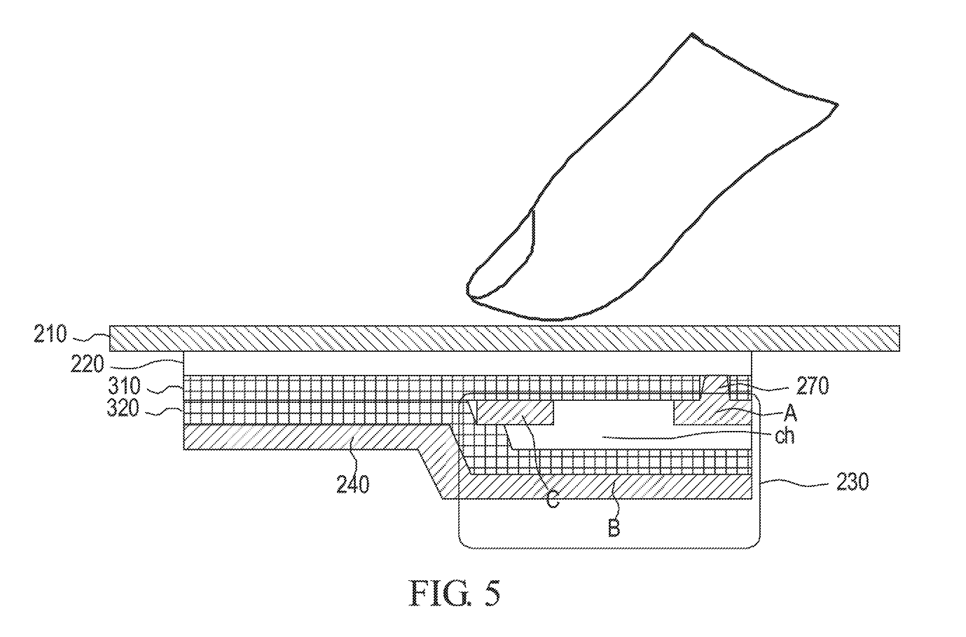

FIG. 5 schematically illustrates an application of the biometric identification device of according to the invention. As shown in FIG. 5, when the finger of a user comes into touch with the substrate 210, the sensor electrodes 220 proceed with a capacitive sensing, and the control unit 260 reads the sensed signals of the sensor electrodes 220 through the sensing signal readout lines 250. In the present invention, since most of the selectors 230, traces 240, and sensing signal readout lines 250 are disposed below and masked by the sensor electrodes 220, the selectors 230, traces 240, and sensing signal readout lines 250 do not produce any sensed signal due to the touch of the finger. Therefore, the control unit 260 can accurately read the sensed signals from the sensor electrodes 220.

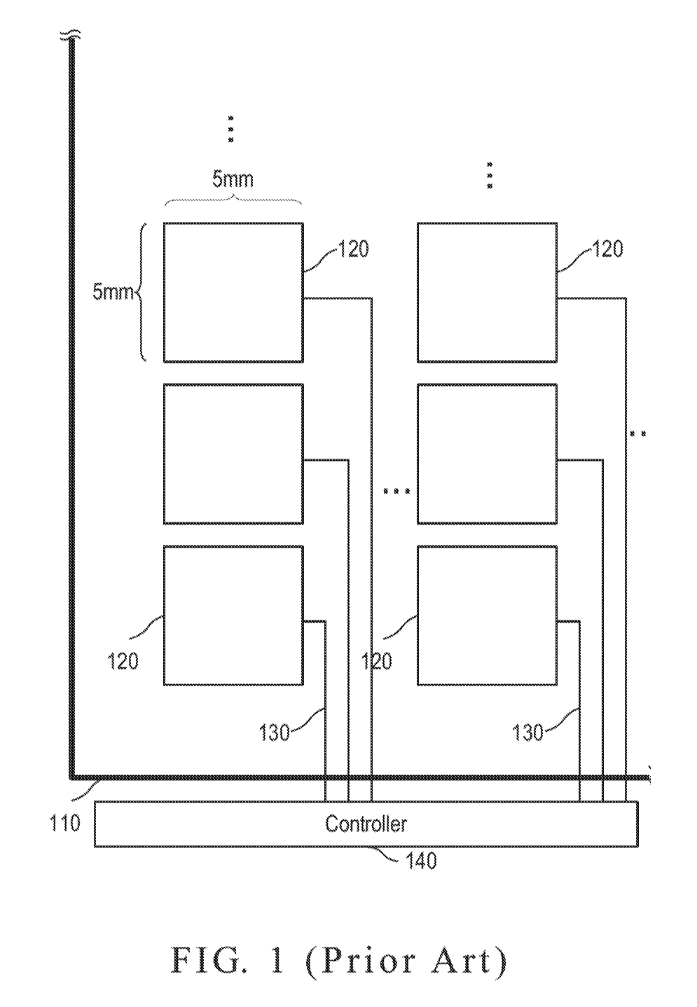

When the size of the sensor electrode is reduced to 100 μm×100 μm, and assuming that the size of a finger is 1 cm×1 cm, one finger can touch 10000 sensor electrodes. In this case, for the prior art shown in FIG. 1, hundred(s) or even thousand(s) of traces and lines may sense the voltage. Because the area of the aforementioned traces and lines is much greater than that of a sensor electrode 120, the voltage induced by the aforementioned traces and lines is greater than that produced by the sensor electrode 120, resulting in that the SNR is greatly reduced. Therefore, the size of the sensor electrode in the prior art cannot be reduced, which is thus not suitable for a high resolution biometric identification device.

By contrast, in the present invention, since most of the selectors 230, traces 240, and sensing signal readout lines 250 are disposed below and masked by the sensor electrodes 220, the selectors 230, traces 240, and sensing signal readout lines 250 do not produce any sensed signal due to the touch of the finger. Therefore, the control unit 260 can accurately read the sensed signals of the sensor electrodes 220. In addition, the present invention makes use the LCD producing process to manufacture the biometric identification device, so that the manufacturing cost is effectively reduced as it is much cheaper than the IC manufacturing process used in the prior fingerprint identification device.

Although the present invention has been explained in relation to its preferred embodiment, it is to be understood that many other possible modifications and variations can be made without departing from the spirit and scope of the invention as hereinafter claimed.

What is claimed is:

1. A biometric identification device having sensor electrodes with masking function, comprising:
a substrate having a surface;
a plurality of sensor electrodes disposed on the surface of the substrate to form a sensing plane;
a plurality of selectors, each corresponding to one sensor electrode and having a first terminal, a second terminal, and a third terminal, wherein the first terminal is connected to a corresponding sensor electrode;
a plurality of selection traces, each connected to the second terminal of at least one of the selectors;
a plurality of sensing signal readout lines, each connected to the third terminal of at least one of the selectors; and
a control unit connected to the plurality of selectors through the plurality of selection traces and the plurality of sensing signal readout lines, so as to read sensed signals of the sensor electrodes corresponding to the selectors, respectively,
wherein the plurality of selectors, the plurality of selection traces, and the plurality of sensing signal readout lines are disposed below and masked by the plurality of sensor electrodes.

2. The biometric identification device as claimed in claim 1, wherein each of the selectors is a thin film transistor.

3. The biometric identification device as claimed in claim 2, wherein the thin film transistor has a gate corresponding to the second terminal, and a source and a drain respectively corresponding to the first terminal and the third terminal, or respectively corresponding to the third terminal and the first terminal.

4. The biometric identification device as claimed in claim 3, wherein each of the sensor electrodes is a polygon, circle, ellipse, rectangle, or square.

5. The biometric identification device as claimed in claim 4, wherein each of the sensor electrodes has a width smaller than or equal to 100 μm and a length smaller than or equal to 100 μm.

6. The biometric identification device as claimed in claim 5, wherein each of the sensor electrode is made of conductive metal material.

7. The biometric identification device as claimed in claim 6, wherein the conductive metal material is selected from the group consisting of: chromium, barium, aluminum, silver, copper, titanium, nickel, tantalum, cobalt, tungsten, magnesium, calcium, potassium, lithium, indium, and an alloy thereof.

8. The biometric identification device as claimed in claim 7, wherein the substrate is a polymer thin film or glass substrate.
